(19) United States
(12) Patent Application Publication
(10) Pub. No.: US 2005/0106864 A1
(43) Pub. Date: May 19, 2005

(54) Process and device for depositing semiconductor layers

(76) Inventors: Holger Jurgensen, Aachen (DE); Gerhard Karl Strauch, Aachen (DE)

Correspondence Address: ST. ONGE STEWARD JOHNSTON & REENS, LLC, 986 BEDFORD STREET, STAMFORD, CT, 06905-5619, US

(21) Appl. No.: 10/922,701

(22) Filed: Aug. 20, 2004

Related U.S. Application Data
(63) Continuation of application No. PCT/EP03/01549, filed on Feb. 15, 2003.

(51) Int. Cl. H01L 21/44; C23C 16/00

(52) U.S. Cl. 438/680; 118/715

(57) ABSTRACT

The invention relates to a device for carrying out a method wherein the process gases are introduced via a common gas inlet element (D) into the process chamber in which a substrate holder (S) is arranged. The gas inlet element has a gas outlet surface which is tempered and which possesses a plurality of gas outlets like a sieve. The substrate holder extends parallel to the gas outlet surface on a horizontal plane and is rotationally driven about a vertical axis. The distance between the substrate holder and the gas outlet surface is not greater than 75 mm. A gas supply device for the reactive gases consisting of at least one metal-organic compound and at least one hydride in addition to another gas is also provided. The isotherms extending above the substrate holder become increasingly flatter as the distance from the gas inlet element becomes smaller, thereby resulting in a higher degree of isothermic homogeneity.

This application is a continuation of pending International Patent Application No. PCT/EP2003/001549, filed Feb. 15, 2003, which designates the United States and claims priority of pending German Application No. 102 07 461.5, filed Feb. 22, 2002.

### FIELD OF THE INVENTION

The invention relates to a process and a device for depositing multicomponent semiconductor layers on at least one substrate.

U.S. Pat. No. 5,871,586 describes a process of this type and an associated device. The device which is known from that document has a reactor housing, inside which there is disposed a rotationally driven substrate holder. This substrate holder is located in the horizontal plane and can rotate about a vertical axis. A gas inlet member is located at a distance above the substrate holder which is less than the radius of the substrate holder. This gas inlet member has a gas inlet surface, which extends parallel to the surface of the substrate holder and has a multiplicity of gas exit openings, which are disposed close together in the manner of a sieve. The gaseous reactive process gases are introduced into the process chamber through these gas exit openings. To deposit a doped solid solution on a substrate located on the substrate holder, a metal organic III component and a V hydride, and also a dopant, are passed through the gas outlet openings. However, it is also possible for a plurality of III components and/or V components to be introduced into the process chamber in order to deposit a solid solution with three or more components on the substrate. The substrate holders are heated from the rear, so that reactions can take place on the surface and/or in the gas phase above the substrate surface. These reactions should preferably be pyrolytic decomposition reactions. The decomposition products or thermally activated starting substances should be prevented from forming adducts. Furthermore, it is necessary for the growth to be homogenous over the entire surface.

Journal of Crystal Growth 195 (1998) 725-732 gives sets of parameters, obtained on the basis of theoretical considerations, for optimizing the homogeneity of the growth rate and the process gas utilization. The authors of this article postulate that short distances between substrate holder surface and gas outlet surface are suitable for optimizing these layer properties. This article assumes the best results to be obtained for process chamber heights in a range between 16 and 25 mm.

U.S. Pat. No. 5,781,693 likewise deals with the deposition of layers on a substrate, with the gaseous starting substances being introduced into the gas phase by means of a showerhead-like gas inlet member.

WO 99/42636 also deals with the introduction of gaseous starting substances into the gas phase by means of a “showerhead”.

Showerhead-like gas inlet members are also disclosed by U.S. Pat. No. 6,086,677, U.S. Pat. No. 5,595,606, U.S. Pat. No. 5,709,757 and U.S. Pat. No. 5,422,139.

The invention is based on the object of improving the process for depositing semiconductor layers having at least three components as mentioned in the introduction in such a way that the crystal composition of the deposited layer has a deviation of significantly better than 1000 ppm (i.e. at most 100 ppm) over its entire area, yet nevertheless the parameters total pressure, total gas flow and rotational speed of the substrate holder can be selected as freely as possible with a view to further optimization.

The object is achieved by the invention given in the claims.

For the claimed process to succeed, it is important for the distance between substrate holder and gas outlet surface to be limited to at most 75 mm.

This limitation of the distance is based on the discovery, made through tests, that the isothermal homogeneity within the process chamber above the substrate in the gas phase is highly dependent on the size of this distance above a chamber height of 75 mm. At less than 50 mm, the homogeneity is not only virtually completely independent of the distance between substrate holder and gas inlet surface, but also is stabilized at a favorable level there. In a vertical reactor, the flow between the gas inlet surface and the substrate plane is dependent on the inlet geometry, on the carrier gas and quantity thereof, on the rotational speed of the substrate holder and on process parameters, such as substrate holder temperature, gas discharge surface temperature and total pressure of the gas phase. The transfer of the starting substances from the gas discharge openings to the surface and the growth of the compound semiconductor crystals are limited by the diffusion. No chemical equilibrium reaction takes place on the surface. Every molecule which diffuses through the surface is completely consumed there and incorporated into the layer. This transport mechanism is described in theory on the basis of interfacial models. Above the substrate surface there is an interface system comprising a plurality of interfaces. A flow interface is formed as a result of the mechanical gas parameters, such as density, flow velocity and geometry of the process chamber. There is also the diffusion interface, which is dependent on the diffusion properties, in particular on the size of the molecules of the individual gases. The diffusion interface is the barrier above which the starting substances must be homogenously distributed in order to ensure uniform transport to the surface. Finally, there is the temperature interface, which is greatly dependent on the geometry and on the flow properties.

Above the substrate, the gas phase has a high vertical temperature gradient. On account of the changing relative velocity of substrate holder with respect to gas discharge surface and the change in total gas flow in the radial direction, this temperature gradient profile is highly dependent on the radial position inside the process chamber. Since each starting substance has a characteristic decomposition energy which is typical of it, and these decomposition energies deviate considerably from one another, the temperature profiles in the gas phase have a considerable influence on the mass transfer of the individual reaction partners to the substrate surface. Although the growth rate may be virtually homogenous over the entire surface, the composition of the layer may change considerably on account of an inhomogenous temperature profile in the plane.

Surprisingly, in addition to the previous studies, tests carried out here have now discovered that as the distance of the gas inlet member above the substrate holder decreases, the isothermals become increasingly flat, with a useable isothermal homogeneity being established even at 75 mm and an optimum isothermal homogeneity being established at a process chamber height of < 50 mm. In this range, the process chamber height is even altogether non-critical, since the isothermal homogeneity scarcely changes in this range. Since the isothermals are virtually completely flat in the process chamber height range of < 50 mm, the starting substances, which flow from above into the gas phase above the substrate in radial manner, decompose virtually under radially identical conditions over the entire surface, so that not only is the growth rate of the layer constant over the entire radius, but so too is the composition of the solid solution.

As further tests have confirmed, the reduction in the process chamber height also leads to a homogenization of the growth rate. The deviations in the layer thickness over the entire layer deposited can be minimized in this way. At the same time, however, it was also possible to determine that other parameters of relevance to the process, namely the total gas flow, also have a considerable influence on the layer thickness homogeneity, and in particular on the efficiency of the process. The lower the total gas flow and the lower the process chamber height, the greater the proportion of the reactive gas supply which is incorporated into the layer. Therefore, it would theoretically be possible to reduce the process chamber height to a minimum (a few millimeters). However, this would mean considerable outlay on cooling the gas inlet in order to prevent the gas discharge surface of the gas inlet member becoming covered with decomposed starting substances. Also, the mechanical conditions restrict the lower limit for the process chamber height.

The surprising discovery that the process chamber height only has an influence on the homogeneity of the composition above approximately 50 mm leads to the option, according to the invention, of selecting the other parameters of relevance to the process in such a way that the efficiency is optimized and at the same time the layer thickness is also homogenous over the substrate. It is possible to achieve layer thickness homogeneities of less than 1%. On account of this surprising discovery, the other process parameters can, at low process chamber height, be optimized with a view to purely economic aspects, i.e. minimizing the total flow and maximizing the rotational speed.

### BRIEF DESCRIPTION OF THE DRAWINGS

The invention is explained in more detail below on with reference to accompanying graphical illustrations.

FIG. 1 shows the result of tests relating to the isothermal homogeneity over various process chamber heights,

FIG. 2 shows an illustration of the sheet resistance over the coated substrate, with the lines running along zones of identical sheet resistance, for a process chamber height of 80 mm,

FIG. 3 shows an illustration corresponding to FIG. 2 for a process chamber height of 50 mm,

FIG. 4 shows an illustration of the photoluminescence emission wavelengths over the coated substrate, with the lines running along zones of identical wavelength, for a process chamber height of 80 mm, with the total gas flow 50 slm and the substrate holder rotational speed 100 rpm.

FIG. 5 shows an illustration corresponding to FIG. 4 for a process chamber height of 20 mm, a total gas flow of 20 slm and a substrate holder rotational speed of 10 rpm,

FIGS. 6 to 29 show isothermal profiles, obtained by simulation calculations, between the process chamber cover D and the substrate holder S, for various process chamber heights, total gas flows and substrate holder rotational speeds.

### DETAILED DESCRIPTION OF THE DRAWINGS

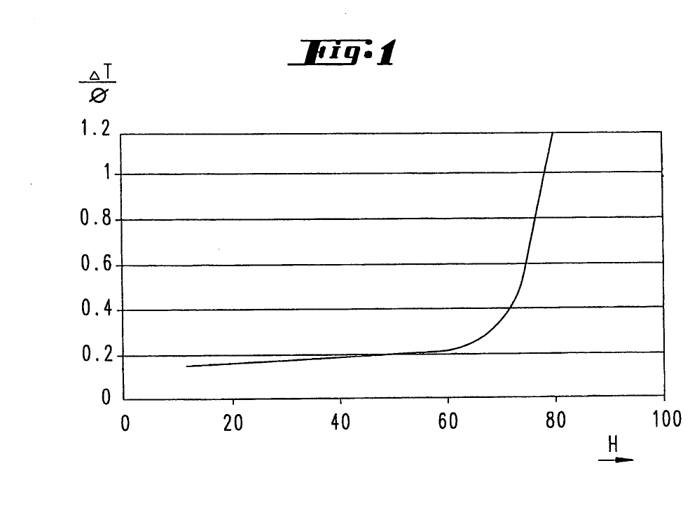

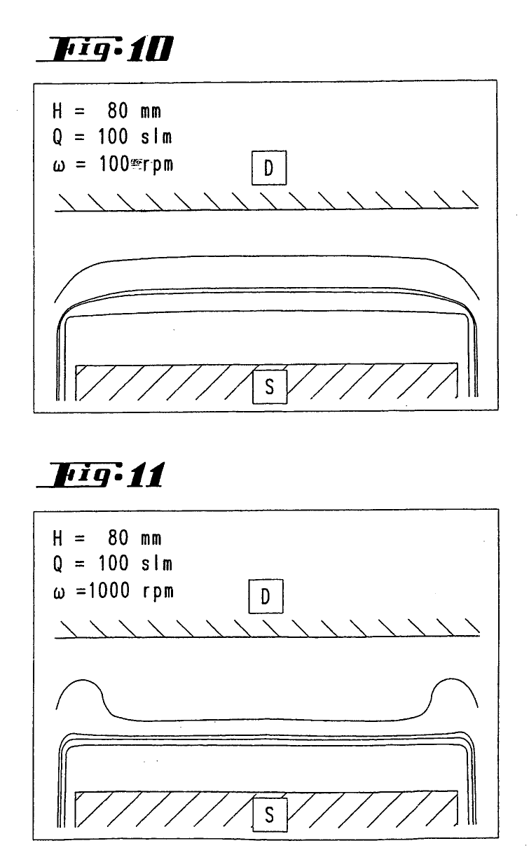

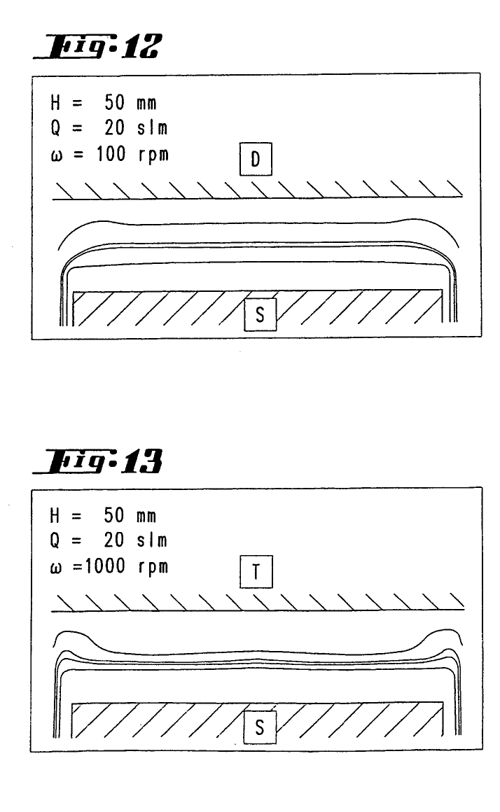

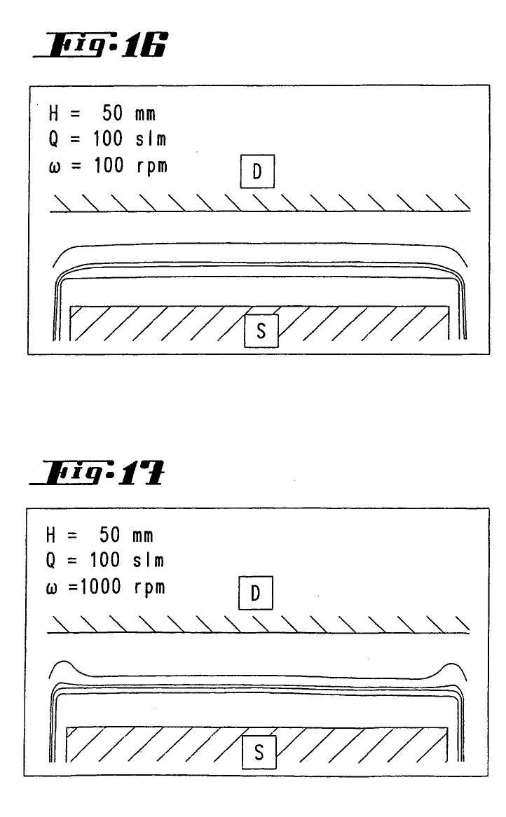

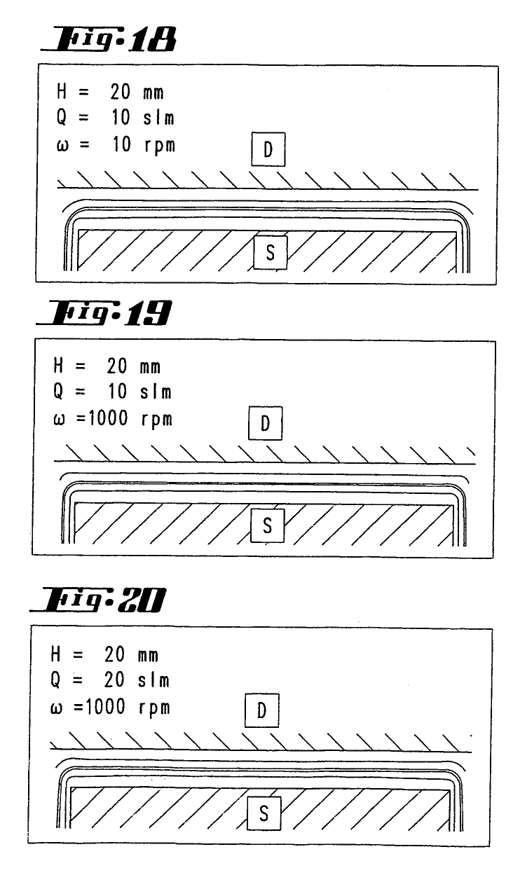

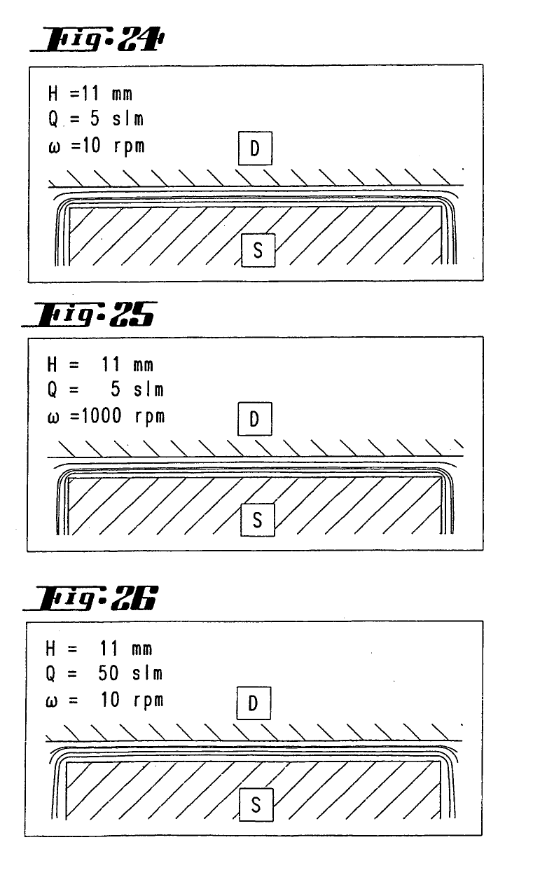

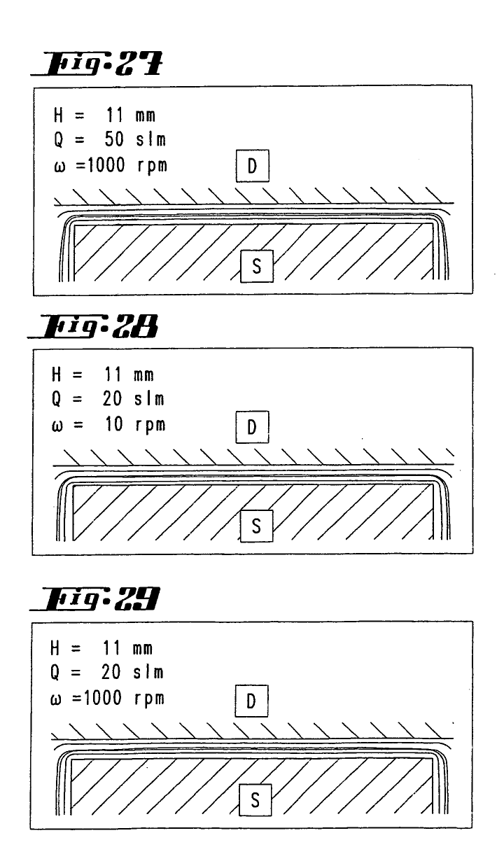

FIG. 1 shows results determined in simulation calculations. Four optimized sets of parameters were compared with one another. The parameters correspond to those shown in FIGS. 11 to 29.

The mean deviation of the isothermal homogeneity from the mean value is plotted for these parameters in FIG. 1. It can be seen that the deviation from the mean decreases as the process chamber height is reduced. Below a process chamber height of 75 mm, the mean is virtually constant. The isothermals are very flat in this range. The isothermals are convex in a range above 80 mm. The result of the flat profile of the isothermals at low process chamber heights is that the gas phase decomposition rates of the reactants involved is virtually identical everywhere. The result of this is that the III/III ratio or the V/V ratio or the incorporation of dopant in the crystal is virtually uniform over the entire layer surface.

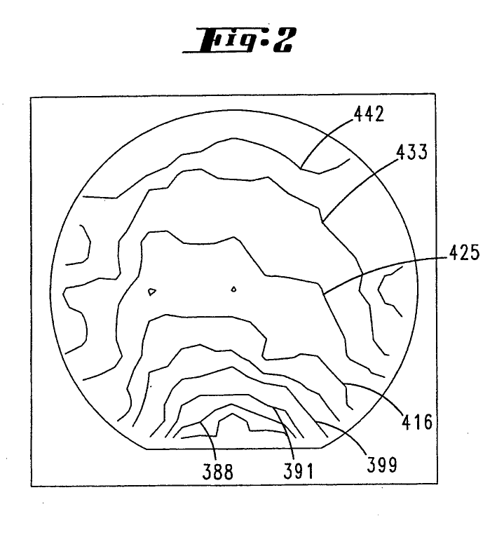

FIGS. 2 and 3 show the sheet resistances of an AlGalnP layer which is n-doped. At process parameters as given above, the process chamber height of 80 mm produces an inhomogenous charge carrier distribution within the layer. This is represented by the inhomogenous sheet resistance. Its deviation from the mean is in this case 5%. FIG. 3 shows the profile of the sheet resistance at a reduced process chamber height, namely 50 mm. In this case too, the sheet resistance is given in ohm/square. The charge carrier distribution is considerably more uniform. The deviation from the mean is 0.5% over the entire surface.

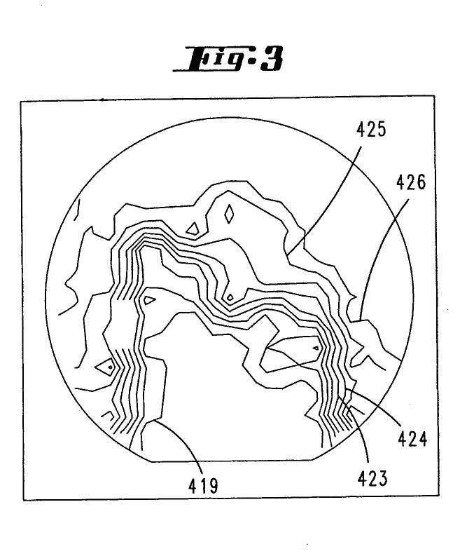

FIGS. 4 and 5 demonstrate the influence of the process chamber height on the homogeneity of the layer composition. These figures represent photoluminescence images of an AlGaInP layer. The surface illustrated in FIG. 4 was deposited in a process chamber with a height of 80 mm. The standard deviation from the mean is in this case 0.42%, corresponding to an absolute variation in the composition of 1157 ppm.

The layer illustrated in FIG. 5 was deposited with a process chamber height of 20 mm, a total gas flow of 20 slm and a substrate holder rotational speed of 10 rpm. In this case, the standard deviation over the entire layer is 0.005%, corresponding to an absolute variation in the composition of 1000 ppm.

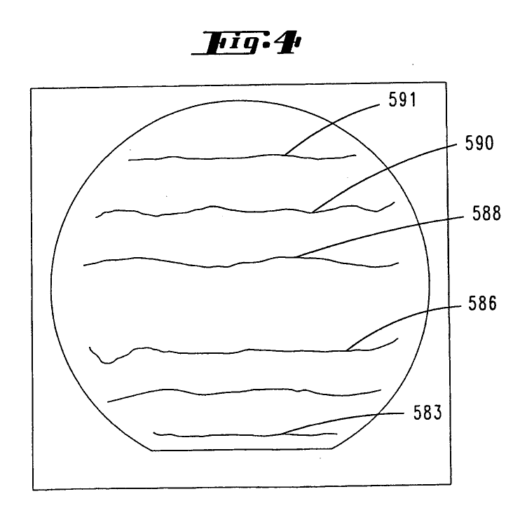

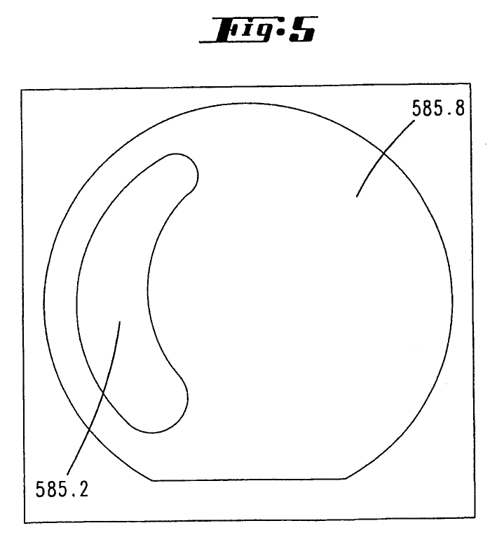

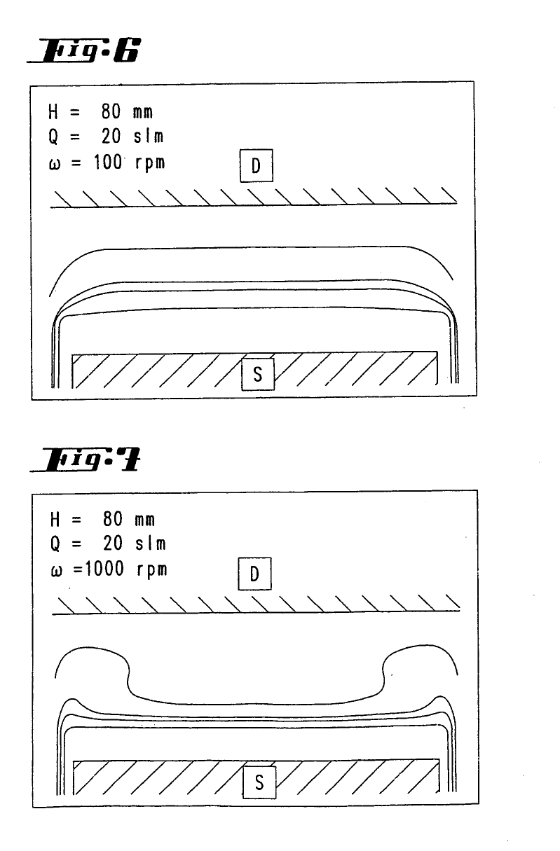

The isothermal profiles illustrated in FIGS. 6 to 11 were calculated for process chamber heights of 80 mm. It can be seen that the total gas flow, which was varied between 20 slm and 100 slm, has a slight influence on the isothermal homogeneity. The isothermal profiles become inhomogenous at the edge region of the substrate holder, which is denoted by S. Useable values are obtained at a total gas flow of 50 slm and a substrate holder rotational speed of 100 rpm. The substrate holder rotational speed has a considerable influence on the profile of the isothermals. At a substrate holder rotational speed of 1000 rpm, the isothermal profile becomes significantly inhomogenous in the edge region and deviates very considerably from the isothermal region in the central region of the process chamber. With a process chamber height of 80 mm, the substrate holder rotational speed can only be varied in a narrow range around 100 rpm, and the total gas flow can only be varied in a narrow range around 50 slm. The tests were carried out using hydrogen as carrier gas. If helium or nitrogen is used, the different viscosity of this gas results in different optimum hydromechanical process parameters. However, the optimum sets of parameters should occur at the same Reynolds number. The gas-mechanical property is also set to the same Reynolds number if the process temperature is varied in the range between 500° C. and 1200° C.

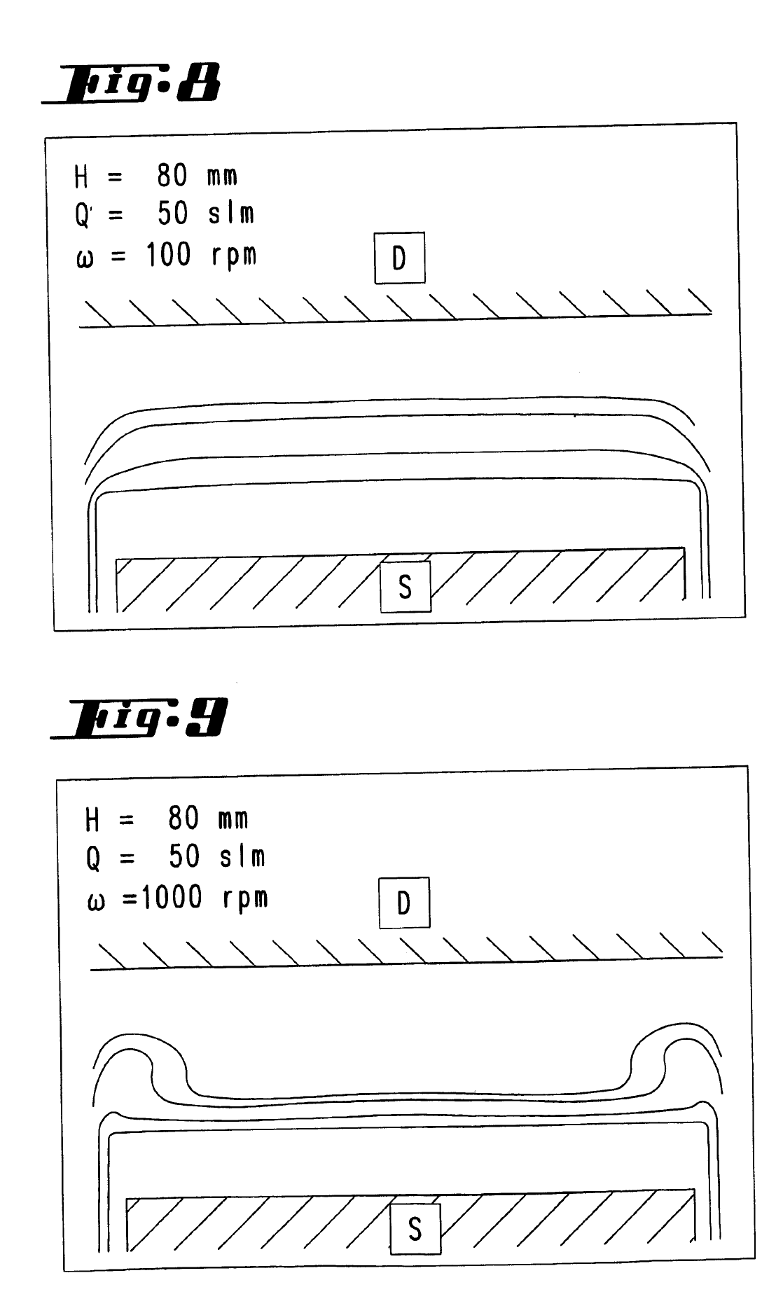

The results illustrated in FIGS. 12 to 17 relate to process chamber heights of 50 mm. The total gas flow was in this case varied in a range between 20 and 100 slm. The substrate holder rotational speed was varied within a range between 100 and 1000 rpm. Over the total gas flow, the only influence to be found was in the critical low-flow range. Above 20 slm, the influence of the total gas flow is virtually zero. In this case too, the total gas flow and the substrate holder rotational speed have a certain influence on the profile of the isothermals, in particular at the edge of the substrate holder. However, the influence of the total gas flow is less than in the case of the results shown in FIGS. 6 to 11.

The influence of the substrate holder rotational speed is also less than at a process chamber height of 80 mm. Reducing the process chamber height from 80 mm to 50 mm means that the other process parameters, such as total gas flow and substrate holder rotational speed, can in fact be varied to a greater extent. The values for the total gas flow can be varied in the range of a factor of three, and the substrate holder rotational speed can be varied in the range of a factor of 10.

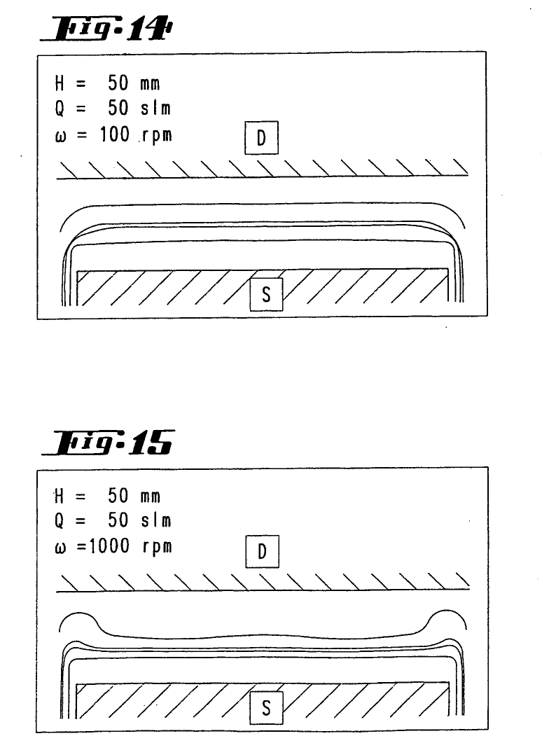

The results illustrated in FIGS. 18 to 23 were obtained with a process chamber height of 20 mm. In this case, the total gas flow was varied in a range between 20 and 50 slm, and the substrate holder rotational speed was varied in a range between 10 and 1000 rpm. The illustrations clearly demonstrate that the total gas flow has virtually no influence on the isothermal profile at the edge of the substrate holder. The substrate holder rotational speed also has scarcely any influence on the profile of the isothermals. With these parameters, it is possible for the total gas flow and substrate holder rotational speed to be varied within a considerably greater range. The total gas flow may quite easily be varied within a range of a factor of > 5, and the substrate holder rotational speed may quite easily be varied within a range of a factor of > 10.

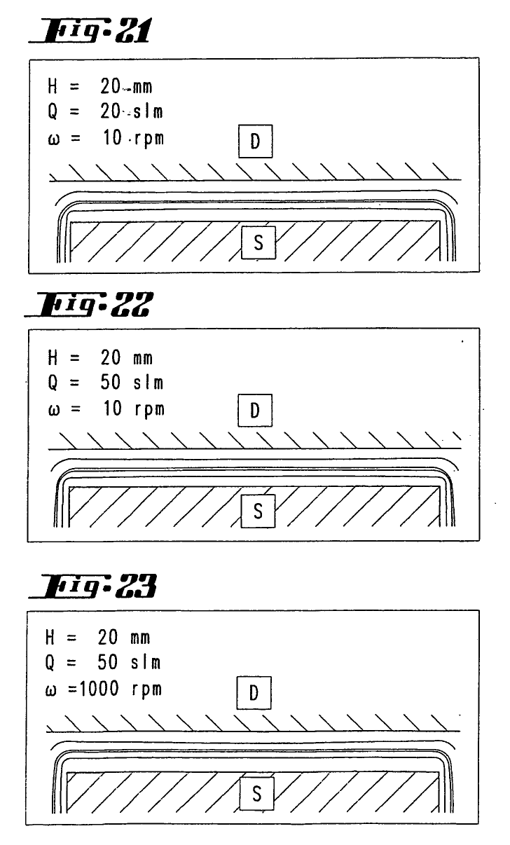

The results shown in FIGS. 24 to 29 were obtained with a process chamber height of 11 mm. In this case, the total gas flow was varied in a range between 5 slm and 50 slm. The substrate holder rotational speed was likewise varied in a range from 10 to 100 rpm. No influence of these parameters on the isothermal profile was recorded. This means that with a process chamber height of just 11 mm, the total gas flow range can be varied by at least a factor of 10. The substrate holder rotational speed can even be varied in a range of a factor of 100 without the isothermal profile changing. The isothermals are completely flat over the entire process chamber.

The process chamber height can in theory be reduced still further. However, this scarcely increases quality below a height of 11 mm. On the contrary, it is highly relevant to the hydrodynamic conditions that the cover D of the process chamber should run completely parallel to the surface of the substrate holder S. The shorter the distance between the process chamber cover D and the substrate holder surface, the more significant the influence of a deviation from the parallel becomes.

For technical reasons, an ideal parallel orientation of process chamber cover and substrate holder surface cannot be realized. Therefore, it is highly advantageous for the process chamber height not to be selected to be less than 10 mm. This applies to substrate holder diameters from 10 to 35 cm. With greater substrate holder diameters, i.e. over 40 cm, it may even be necessary for the process chamber height to be limited to values of over 10 mm, for example to 20 mm. The processes are generally carried out at 750° C. and at typical total pressures of between 150 mbar and 1000 mbar, preferably between 200 and 500 mbar. In this case, generally only the substrate holder is heated. The process chamber cover D, which is formed as a shower head, by contrast, is cooled, and consequently a very high uptake and dissipation of heat is required at the surface of the process chamber cover.

However, on account of inevitable manufacturing tolerances, a lower limit for the process chamber height may also be required. These deviations, which are substantially caused by statistical fluctuations, mean that the process chamber height range which is optimum in practice may, in particular also taking account of the diameter of the substrate holder and the viscosity of the gas used, be between 10 and 75 mm. However, it is preferable for the process chamber height to be in a range of less than 50, 40, 30, 25 or 10 mm.

All features disclosed are (inherently) pertinent to the invention. The disclosure content of the associated/appended priority documents (copy of the prior application) is hereby incorporated in its entirety in the disclosure of the application, partly with a view to incorporating features of these documents in claims of the present application.

1. Process for depositing multicomponent semiconductor layers on at least one substrate, comprising the following features:
at least three reactive process gases are used, in order to deposit either a doped solid solution with two or more components or an undoped solid solution with three or more components;
the process gases are introduced, by means of a common gas inlet member, into a process chamber, in which the substrate is located on a substrate holder;
the gas inlet member has a gas outlet surface, the temperature of which is controlled and which has a multiplicity of gas exit openings, in the manner of a sieve;
the substrate holder extends parallel to the gas outlet surface in the horizontal plane and is driven in rotation about a vertical axis;
the distance between the substrate holder and the gas outlet surface is no greater than 75 mm;
the reactive gases contain at least one metal organic compound and at least one hydride.

2. Process according to claim 1 or in particular according thereto, characterized in that the substrate holder is surrounded by an annular gas outlet member, from which a gas discharge line leads to a pump.

3. Process according to claim 1, characterized in that the total pressure in the process chamber is set in a range from at least Pₘᵢₙ=20 mbar to Pₘₐₓ=1000 mbar.

4. Process according to claim 1, characterized in that the total gas flow through the gas outlet member is set in a range from Qₘᵢₙ=5 slm to Qₘₐₓ=200 slm.

5. Process according to claim 1, characterized in that the substrate holder rotational speed is set in a range from Rₘᵢₙ=10 rpm to Rₘₐₓ=2000 rpm.

6. Process according to claim 1, characterized in that the semiconductor layers are III, V semiconductor layers, and in further process steps the semiconductor layers are processed further to form LEDs, solar cells, laser HBTs and HEMTs.

7. Process according to claim 1, characterized in that at a substrate temperature in the range between 500° C. and 1200° C. or in particular of approximately 750° C., the total gas flow, for a process chamber height of 75 mm, is between 30 and 100 slm, and the substrate holder rotational speed is between 100 and 1000 rpm.

8. Process according to claim 1, characterized in that at a substrate temperature in the range between 500° C. and 1200° C. or in particular of approximately 750° C., the total gas flow, for a process chamber height of 50 mm, is between 30 and 100 slm and the substrate holder rotational speed is between 100 and 1000 rpm.

9. Process according to claim 1, characterized in that at a substrate temperature in the range between 500° C. and 1200° C., or in particular of approximately 750° C., the total gas flow, for a process chamber height of 20 mm, is between 10 and 50 slm and the substrate holder rotational speed is between 10 and 1000 rpm.

10. Process according to claim 1, characterized in that at a substrate temperature in the range between 500° C. and 1200° C., or in particular of approximately 750° C., the total gas flow, for a process chamber height of 11 mm, is between 5 and 50 slm, and the substrate holder rotational speed is between 10 and 1000 rpm.

11. Process according to claim 1, characterized in that the process chamber height is greater than 11, 15 or 20 mm.

12. Device for carrying out the process according to claim 1, in which the process gases are introduced into the process chamber by means of a common gas inlet member, and in the process chamber there is a substrate holder, the gas inlet member having a gas outlet surface, the temperature of which is controlled and which has a multiplicity of gas exit openings in the manner of a sieve, the substrate holder extending parallel to the gas outlet surface in the horizontal plane and being driven in rotation about a vertical axis, the distance between the substrate holder and the gas outlet surface being no greater than 75 mm, and having a gas supply means for the reactive gases, which consist of at least one metalorganic compound and at least one hydride and a further gas of this type.

13. Device according to claim 12 or in particular according thereto, characterized in that the gas inlet member is water-cooled in the region of the gas outlet surface.

14. Device according to claim 12, characterized in that the distance between substrate holder and gas outlet surface (i.e. the process chamber height) is less than 50, 40, 30, 25, 20, 16 or 11 mm.

15. Device according to claim 12, characterized in that the distance between the substrate holder and gas outlet surface (process chamber height) is greater than 11, 15 or 20 mm.

16. Device according to claim 12, characterized in that the diameter of the substrate holder corresponds to the diameter of the gas outlet surface and is greater than 10, 20, 30, 35, 40 or 45 cm.
